(19) United States
(12) Patent Application Publication
(10) Pub. No.: US 2014/0021501 A1
(43) Pub. Date: Jan. 23, 2014

(54) Light Emitting Diode Device with Enhanced Heat Dissipation, and the Method of Preparing the Same

(71) Applicant: National Cheng Kung University, Tainan City (TW)

(72) Inventors: In-Gann CHEN, Tainan City (TW); Yung-Tang NIEN, Changhua County (TW); Chia-Wei MA, Tainan City (TW)

(21) Appl. No.: 13/945,971

(22) Filed: Jul. 19, 2013

(30) Foreign Application Priority Data
Jul. 19, 2012 (TW) 101126046

(51) Int. Cl. H01L 33/44

(52) U.S. Cl. CPC H01L 33/44
USPC 257/98; 438/29

(57) ABSTRACT

The present invention provides a light emitting diode device with enhanced heat dissipation, and the method of preparing the same. By forming the heat dissipating holes and trenches on the phosphor layer, and filling the heat dissipating holes and trenches on the phosphor layer with thermal conducting materials, the service life of the light emitting diode can be longer by reducing the thermal effect and improving the heat dissipation.

### CROSS REFERENCE TO RELATED APPLICATION

This application claims the benefits of the Taiwan Patent Application Serial Number 101126046, filed on Jul. 19, 2012, the subject matter of which is incorporated herein by reference.

### BACKGROUND OF THE INVENTION

1. Field of the Invention

The present invention relates to a light emitting diode device with enhanced heat dissipation and a method of preparing the same. 2. Description of Related Art

With the development of technology, the applications of light emitting diode are increasing, the peripheral integrated circuit elements and dissipation techniques are getting more sophisticated, and public demand for high power light emitting diode is growing. However, the high-power light emitting diode usually has a problem of poor heat dissipation, and resulting in deterioration of the light emitting diode chip; therefore, the dissipation technology of the light emitting diode must be further improved to meet the demand for a means for cooling high-power light emitting diodes.

A common heat dissipation technique uses metal or ceramic substrates as heat dissipating medium, combining light emitting diode chips and metal sheet with heat conductive glue or eutectic alloy can significantly improve the thermal conductivity. However, when using the metal substrate as a heat dissipating medium, due to the thermal expansion coefficient of the metal substrate being larger than that of the light emitting diode chip, the damage to the light emitting diode chips often occurs when the light emitting diode chips were powered with a high electric current.

In order to solve the above mentioned problems, the present invention provides a light emitting diode device with enhanced heat dissipation, by forming heat dissipating holes and heat dissipating trenches on the phosphor layer to improve the heat dissipation of the light emitting diode devices.

### SUMMARY OF THE INVENTION

The main purpose of the present invention is to provide a light emitting diode device with enhanced heat dissipation, specifically, to form heat dissipating holes on the phosphor layer of the light emitting diode device, and filling with heat conductive materials into the heat dissipating holes, then the heat generated during the operation of the light emitting diodes can be dissipated not only through the heat conducting substrate below, but also through the phosphor layer above.

The light emitting diode device with enhanced heat dissipation of the present application comprises a light emitting diode chip having a light emitting surface; a phosphor layer, configured on the light emitting surface of the light emitting diode chip, wherein the phosphor layer has a plurality of heat dissipating holes, and the plurality of heat dissipating holes penetrate the phosphor layer; and a heat dissipating material filling the heat dissipating holes, and the heat expansion coefficient difference between the phosphor layer and the heat dissipating material is less than 20 ppm/K. When the light emitting diode device is operating, the heat generated will cause the expansion of the heat conductive material and the phosphor layer, and if the difference of thermal expansion coefficient between the heat conductive material and the phosphor layer is too large, the difference of the expanded volume also will be too large and the cracks and the interfacial peeling is likely to occur, causing damages to the phosphor layer.

Further, a plurality of heat dissipating trenches are formed on the phosphor layer, the plurality of heat dissipating trenches are formed on the emitting surface or receiving surface of the phosphor layer thereof, and the plurality of heat dissipating trenches are extended from the plurality of heat dissipating holes, and the plurality of heat dissipating trenches are filled with the heat dissipating material.

The phosphor layer described above may be a phosphor gel, a phosphor plastic, or a phosphor ceramic, wherein the material of the phosphor layer is an oxide, a nitride, a oxynitride, a silicate, an aluminate, a phosphate, a sulfide, a sulfur oxide, or mixtures thereof; the material of the phosphor layer is preferred to be Y₃Al₅O₁₂, Y₂O₃, CaTiO₃, Ca₂Y₂Si₂O₉, CaAlSiN₃, SiAlON, Zn₂SiO₄, (Sr,Ba)Al₂O₄, ZnS, or Y₂O₂S, wherein Y₃Al₅O₁₂ is most preferable.

In addition, the thermal conductivity of the heat dissipating material is 5˜400 W/m·K, wherein the heat dissipating material may be silicon, gallium arsenide, gallium nitride, aluminum oxide, aluminum, copper, silver, silicon carbide, boron nitride, or mixtures thereof; wherein copper is most preferable.

The other aspect of the present invention is related to a method of manufacturing a light emitting diode device with enhanced heat dissipation, which includes: providing a light emitting diode chip having a light emitting surface; forming a phosphor layer on the light emitting surface of the light emitting diode; forming a plurality of heat dissipating holes in the phosphor layer, and the plurality of heat dissipating holes penetrate the phosphor layer; and filling the plurality of heat dissipating holes with heat conductive material, wherein the heat expansion coefficient difference between the phosphor layer and the heat dissipating material is less than 20 ppm/K.

The phosphor layer described above is a phosphor gel, a phosphor plastic, or a phosphor ceramic, wherein the material of the phosphor layer is an oxide, a nitride, a oxynitride, a silicate, an aluminate, a phosphate, a sulfide, a sulfur oxide, of mixtures thereof, and is preferred to be Y₃Al₅O₁₂, Y₂O₃, CaTiO₃, Ca₂Y₂Si₂O₉, CaAlSiN₃, SiAlON, Zn₂SiO₄, (Sr,Ba)Al₂O₄, ZnS, or Y₂O₂S, wherein Y₃Al₅O₁₂ is more preferable.

Further, when forming the plurality of the heat dissipating holes in the phosphor layer, a plurality of the heat dissipating trenches are further formed on a emitting surface or a receiving surface of the phosphor layer, wherein the plurality of heat dissipating trenches extend from the plurality of heat dissipating holes and the plurality of heat dissipating trenches are filled with the heat dissipating material.

The plurality of heat dissipating holes and the plurality of heat dissipating trenches are formed by laser, mechanical drilling, or etching method. And the heat conductive material is filled in the holes in the phosphor layer using doctor blade method, deposition method, or sputtering.

The thermal conductivity of the heat dissipating material is 5˜400 W/m·K, wherein the heat dissipating material is silicon, gallium arsenide, gallium nitride, aluminum oxide, aluminum, copper, silver, silicon carbide, boron nitride, or mixtures thereof, wherein copper is preferable. Due to the opacity of copper, copper has the advantages of adjusting the color temperature as well as heat dissipation.

The light emitting diode device with enhanced heat dissipation according to the present invention, wherein the heat generated due to the light emitting may be sufficiently dissipated from the phosphor layer with enhanced heat dissipation. The heat dissipating effect is excellent and the heat dissipation problem of high-power light emitting diodes can be effectively solved.

### BRIEF DESCRIPTION OF THE DRAWINGS

FIG. 1 is a cross-section view of a preferred embodiment.

FIG. 2 is a top view of a preferred embodiment.

FIG. 3 is a cross-sectional view of a preferred implementation of the present invention.

FIG. 4 is a cross-sectional view of a preferred implementation of the present invention; and

FIG. 5 is a cross-sectional view of a preferred implementation of the present invention.

### DETAILED DESCRIPTION OF THE PREFERRED EMBODIMENT

For a person having skills in the art of the present application to understand the present invention more specifically, the detailed description of the technical features and the desired effect of the present invention is described in the following embodiments of the present invention with references to figures.

### Embodiment

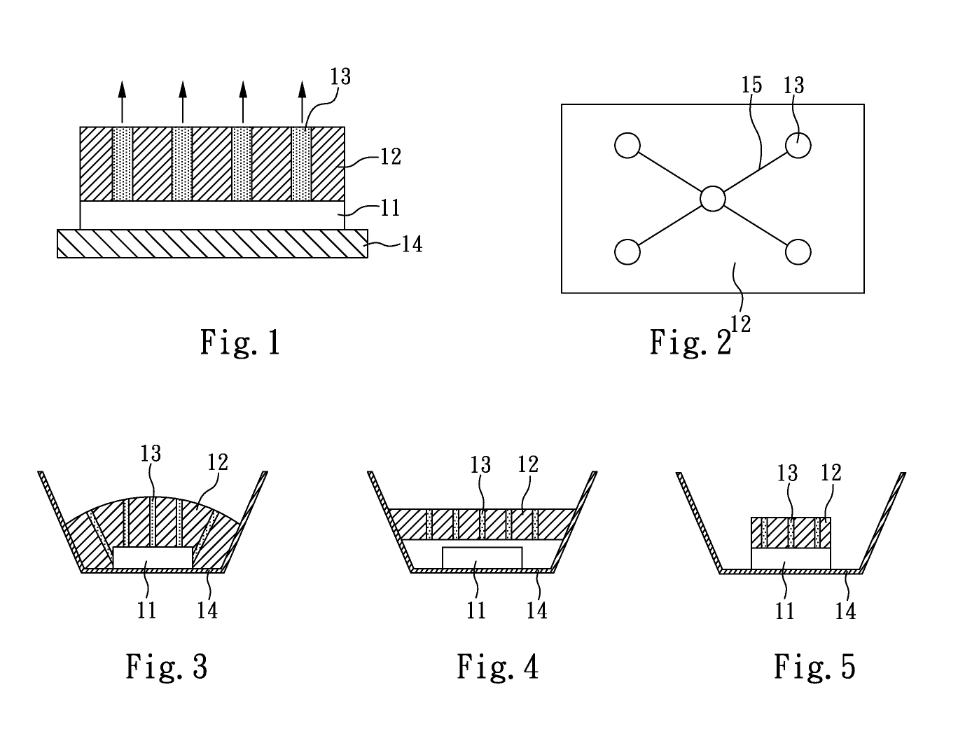

The embodiment is a method of preparing a light emitting diode device with enhanced heat dissipation. In reference to FIG. 1 and FIG. 2, FIG. 1 is the cross-section view of a light emitting device with enhanced heat dissipation of a preferred embodiment. FIG. 2 is the top view of a light emitting device with enhanced heat dissipation of a preferred embodiment. A light emitting diode chip 11 is placed on a substrate 14, and the material of the substrate 14 may be plastic material, or metal or ceramic material with thermal conductivity known in the art; the light emitting diode chip 11 is attached to the substrate 14 by the method known in the art. The light emitting diode 11 is covered with a phosphor layer, and using laser drilling to create heat dissipating holes 13 through the phosphor layer 12 and patterned heat dissipating trenches 15 on the surface of the phosphor layer. After forming heat dissipating holes 13 through the phosphor layer 12, the heat conducting material is filled in the heat dissipating holes 13 and heat dissipating trenches 15 using a scraper to form the light emitting diode device with enhanced heat dissipation.

The method of preparing a light emitting diode device with enhanced heat dissipation, wherein the phosphor layer is made of phosphor gel, a cross-section view of a preferred embodiment is shown in FIG. 3; wherein the phosphor layer is made of plastic, a cross-section view of a preferred embodiment is shown in FIG. 4; and wherein the phosphor layer is made of ceramic, a cross-section view of a preferred embodiment is shown in FIG. 5. But the present invention is not limited.

### Embodiment 1

The embodiment 1 of the present invention is the method of preparing a light emitting diode device with enhanced heat dissipation, and testing its dissipating effect. A phosphor layer with thickness of 0.16 mm using a phosphor ceramic plate as a phosphor material is provided. Laser drilling method is used to form a plurality of heat dissipating holes through the phosphor layer, and a scraper is used to fill the plurality of heat dissipating holes with copper as a heat conducting material in order to form a phosphor layer with enhanced heat dissipation. The test method of testing the heat dissipation effect involves using an infrared light with 3 W power as a heat source, and irradiating the phosphor layer with enhanced heat dissipation for 2 minutes. After, 2 minutes of irritating, the thermal image of the phosphor layer is shot by the NEC G100EX thermal imager, and after the analysis of the thermal image, the maximum surface temperature of the phosphor layer is 244.1° C.

### COMPARATIVE EXAMPLE 1

The comparative example 1 is a method of preparing a light phosphor layer with heat dissipating holes, and testing its dissipating effect. A phosphor layer with thickness of 0.16 mm using phosphor ceramic plate as a phosphor material is provided. Laser drilling method is used to form a plurality of heat dissipating holes through the phosphor layer and a phosphor layer with dissipating holes is formed. The test method of testing the heat dissipation effect involves using an infrared light with 3 W power as a heat source, and irradiating the phosphor layer with heat dissipating holes for 2 minutes. After 2 minutes of irritating, the thermal image of the phosphor layer is shot by the NEC G100EX thermal imager, and after the analysis of the thermal image, the maximum surface temperature of the phosphor layer is 67.8° C.

### COMPARATIVE EXAMPLE

The comparative example 2 is the method of preparing a light phosphor layer, and testing its dissipating effect. A phosphor layer with thickness of 0.16 mm using phosphor ceramic plate as a phosphor material is provided. The test method of testing the heat dissipation effect involves using an infrared light with 3 W power as a heat source, and irradiating the phosphor layer for 2 minutes. After 2 minutes of irritating, the thermal image of the phosphor layer is shot by the NEC G100EX thermal imager, and after the analysis of the thermal image, the maximum surface temperature of the phosphor layer is 68.0° C.

From the above experimental results of the embodiment and the comparative examples, after irradiation, the surface temperature of the phosphor layer with enhanced heat dissipation is increased to 244.1° C., which indicates that the heat dissipation effect of the phosphor layer with enhanced heat dissipation is excellent. In comparison to embodiment 1, after irradiation, the surface temperature of the phosphor layer with heat dissipating holes of the comparative example 1 and of the phosphor layer of the comparative example 2 do not increase significantly, which indicates that the phosphor layer having heat dissipating holes of the comparative example 1 and the phosphor layer of the comparative example 2 do not possess heat dissipating functionality. The phosphor layer with enhanced heat dissipation is proved to have an excellent effect of heat dissipation.

The above embodiments are for the convenience of description and examples only, the scope of the present invention is not limited hereinafter.

What is claimed is:

1. A light emitting diode device with enhanced heat dissipation, comprising:
a light emitting diode chip having a light emitting surface;
a phosphor layer, configured on the light emitting surface of the light emitting diode chip, wherein the phosphor layer has a plurality of heat dissipating holes, and the plurality of heat dissipating holes passes through the phosphor layer; and
a heat dissipating material filling the heat dissipating holes, and the heat expansion coefficient difference between the phosphor layer and the heat dissipating material is less than 20 ppm/K.

2. The light emitting diode device as claimed in claim 1, wherein the phosphor layer further has a plurality of heat dissipating trenches configuring on an emitting surface or a receiving surface thereof, and the plurality of heat dissipating trenches is extended from the plurality of heat dissipating holes, and the plurality of heat dissipating trenches is filled with the heat dissipating material.

3. The light emitting diode device as claimed in claim 1, wherein the phosphor layer is a phosphor gel, a phosphor plastic, or a phosphor ceramic.

4. The light emitting diode device as claimed in claim 1, wherein the material of the phosphor layer is an oxide, a nitride, a oxynitride, a silicate, an aluminate, a phosphate, a sulfide, a sulfur oxide, or mixtures thereof.

5. The light emitting diode device as claimed in claim 4, wherein the material of the phosphor layer is Y₃Al₅O₁₂, Y₂O₃, CaTiO₃, Ca₂Y₂Si₂O₉, CaAlSiN₃, SiAlON, Zn₂SiO₄, (Sr,Ba)Al₂O₄, ZnS, or Y₂O₂S.

6. The light emitting diode device claimed in claim 4, wherein the material of the phosphor layer is Y₃Al₅O₁₂.

7. The light emitting diode device claimed in claim 1, wherein the thermal conductivity of the heat dissipating material is 5˜400 W/m·K.

8. The light emitting diode device claimed in claim 1, wherein the heat dissipating material is silicon, gallium arsenide, gallium nitride, aluminum oxide, aluminum, copper, silver, silicon carbide, boron nitride, or mixtures thereof.

9. The light emitting diode device claimed in claim 1, wherein the heat dissipating material is copper.

10. A method of manufacturing a light emitting diode device with enhanced heat dissipation, including:
providing a light emitting diode chip having a light emitting surface;
forming a phosphor layer on the light emitting surface of the light emitting diode;
forming a plurality of heat dissipating holes in the phosphor layer, and the plurality of heat dissipating holes passes through the phosphor layer; and
filling the plurality of heat dissipating holes with heat conductive material, wherein the heat expansion coefficient difference between the phosphor layer and the heat dissipating material is less than 20 ppm/K.

11. The method claimed in claim 10, wherein when forming the plurality of the heat dissipating holes in the phosphor layer, a plurality of the heat dissipating trenches are further formed on a emitting surface or a receiving surface of the phosphor layer, wherein the plurality of heat dissipating trenches extends from the plurality of heat dissipating holes and the plurality of heat dissipating trenches is filled with the heat dissipating material.

12. The method claimed in claim 10, wherein the plurality of heat dissipating holes is formed by laser, mechanical drilling, or etching.

13. The method claimed in claim 11, wherein the plurality of heat dissipating trenches is formed by laser, mechanical drilling, or etching.

14. The method claimed in claim 10, wherein the phosphor layer is a phosphor gel, a phosphor plastic, or a phosphor ceramic.

15. The method claimed in claim 10, wherein the material of the phosphor layer is an oxide, a nitride, an oxynitride, a silicate, an aluminate, a phosphate, a sulfide, a sulfur oxide, of mixtures thereof.

16. The method claimed in claim 15, wherein the material of the phosphor layer is Y₃Al₅O₁₂, Y₂O₃, CaTiO₃, Ca₂Y₂Si₂O₉, CaAlSiN₃, SiAlON, Zn₂SiO₄, (Sr,Ba)Al₂O₄, ZnS, or Y₂O₂S.

17. The method claimed in claim 15, wherein the material of the phosphor layer is Y₃Al₅O₁₂.

18. The method claimed in claim 10, wherein the thermal conductivity of the heat dissipating material is 5˜400 W/m·K.

19. The method claimed in claim 10, wherein the heat dissipating material is silicon, gallium arsenide, gallium nitride, aluminum oxide, aluminum, copper, silver, silicon carbide, boron nitride, or mixtures thereof.

20. The method claimed in claim 10, wherein the heat dissipating material is copper.
